(19) United States
(12) Patent Application Publication
(10) Pub. No.: US 2024/0125855 A1
(43) Pub. Date: Apr. 18, 2024

(54) Electrochemical Process Manifolds for Battery Cell Monitoring

(71) Applicant: NATIONAL INSTRUMENTS CORPORATION, Austin, TX (US)

(72) Inventors: Brian MacCleery, Austin, TX (US); Martin Weiss, Austin, TX (US)

(21) Appl. No.: 18/489,535

(22) Filed: Oct. 18, 2023

Related U.S. Application Data
(60) Provisional application No. 63/380,040, filed on Oct. 18, 2022.

(51) Int. Cl. G01R 31/36; G01R 31/378; G01R 31/3828; G01R 31/3842; G01R 31/392; G01R 31/396; H01M 10/48; H01M 50/569

(52) U.S. Cl. CPC G01R 31/3648; G01R 31/378; G01R 31/3828; G01R 31/3842; G01R 31/392; G01R 31/396; H01M 10/486; H01M 50/569

(57) ABSTRACT

Systems, methods and devices for constructing an electrochemical process manifold (EPM) for a battery cell during a formation process. The current through the cell is controllably adjusted to charge or discharge the cell. The temperature and/or pressure may be controllably adjusted along with the current. At each of a plurality of time steps as the current is controllably adjusted, the voltage across the cell is measured and integrated over time to obtain a voltage-hours value for each time step. A data point is stored in memory for each time step that includes the measured voltage, the voltage-hours value, and the current through the cell at the respective time step. The data points for each time step are mapped onto an EPM, and the EPM is stored in a non-transitory computer-readable memory medium.

### PRIORITY INFORMATION

This application claims priority to U.S. Provisional Patent Application No. 63/380,040, titled “Electrochemical Process Manifolds for Battery Cell Monitoring” and filed Oct. 18, 2022, which is hereby incorporated by reference in its entirety as though fully and completely set forth herein.

### FIELD OF THE INVENTION

The present invention relates to the field of battery cell manufacturing and formation.

### DESCRIPTION OF THE RELATED ART

A typical workflow for battery cell constructions involves cell manufacturing, formation, and aging. Yields in battery cell manufacturing processes are typically below 80% due to variability in the involved electrochemical processes, and this yield rate has been difficult to improve. In addition, formation and aging are time-consuming processes that take on the order of days to complete. Aging includes repeatedly taking cell measurements to detect defects, but defects may be difficult to detect and may present significant risk to product performance and safety. Current implementations to address these issues become cost prohibitive at scale. Battery cell factories employ equipment and infrastructure to cycle and age a massive number of cells, potentially millions at full capacity. Accordingly, improvements in the field, in particular, regarding improvements in efficient and effective high-volume battery cell formation, aging and manufacturing are desired.

### SUMMARY OF THE INVENTION

Various embodiments are presented herein of systems, methods and devices for constructing an electrochemical process manifold (EPM) for a battery cell during a formation process.

In some embodiments, the current through the cell (or the voltage across the cell) is controllably adjusted to charge or discharge the cell. In some embodiments, the temperature and/or pressure may be controllably adjusted along with the current.

In some embodiments, at each of a plurality of time steps as the current is controllably adjusted, the voltage across the cell is measured and integrated over time to obtain a voltage-hours value for each time step. A data point may be stored in memory for each time step that includes the measured voltage, the voltage-hours value, and the current through the cell at the respective time step.

In some embodiments, rather than controllably adjusting the current through the cell and periodically measuring the voltage, the voltage across the cell may be controllably adjusted and the current may be periodically measured.

In some embodiments, the data points for each time step are mapped onto an electrochemical process manifold (EPM).

In some embodiments, the EPM is stored in a non-transitory computer-readable memory medium.

This Summary is intended to provide a brief overview of some of the subject matter described in this document. Accordingly, it will be appreciated that the above-described features are only examples and should not be construed to narrow the scope or spirit of the subject matter described herein in any way. Other features, aspects, and advantages of the subject matter described herein will become apparent from the following Detailed Description, Figures, and Claims.

### BRIEF DESCRIPTION OF THE DRAWINGS

A better understanding of the present invention can be obtained when the following detailed description of the preferred embodiment is considered in conjunction with the following drawings, in which:

FIG. 1 illustrates a production workflow for battery cells, according to some embodiments;

FIG. 2 shows a computer system coupled to a controller, according to some embodiments;

FIG. 3 is a basic computer system block diagram, according to some embodiments;

FIG. 4 is a flowchart diagram illustrating a method for constructing an electrochemical process manifold (EPM) by controllably adjusting the current through a cell, according to some embodiments;

FIG. 5 is a flowchart diagram illustrating a method for constructing an electrochemical process manifold (EPM) by controllably adjusting the voltage across a cell, according to some embodiments;

FIG. 6 is a schematic illustration of a cell formation setup, according to some embodiments;

FIG. 7 illustrates an example waveform for controllably adjusting current through a cell, according to some embodiments;

FIG. 8 illustrates a zoomed-in portion of the waveform illustrated in FIG. 7, according to some embodiments;

FIG. 9 illustrates Vcross voltage measurements for different charge values, according to some embodiments;

FIG. 10 illustrates an example of a displayed EPM, according to some embodiments; and

FIG. 11 illustrates two different examples of an EPM, according to some embodiments.

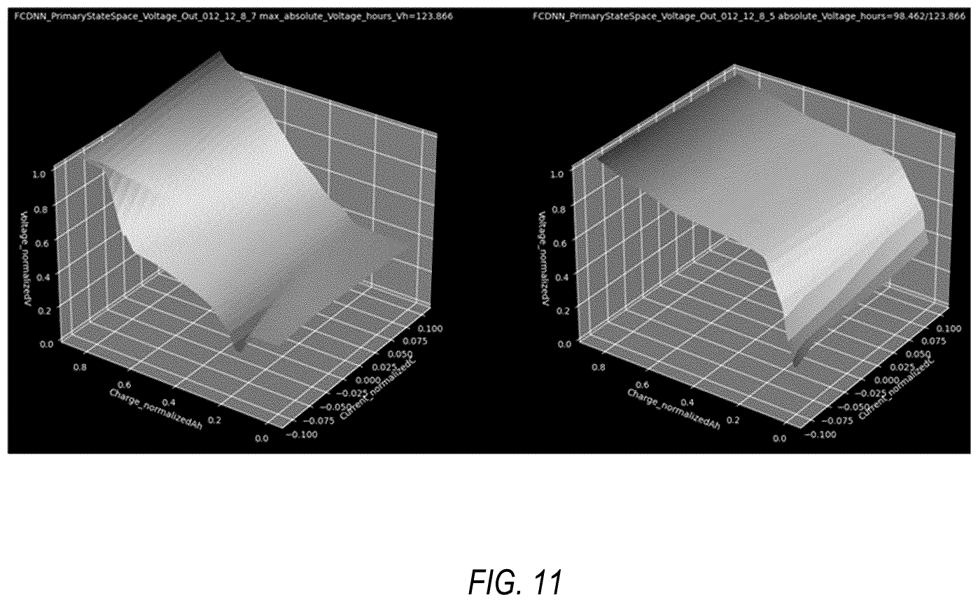

While the invention is susceptible to various modifications and alternative forms, specific embodiments thereof are shown by way of example in the drawings and are herein described in detail. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims.

### DETAILED DESCRIPTION OF THE INVENTION

### Acronyms

The following is a listing of the acronyms used in the present application:
EPM: Electrochemical Process Manifold
DUT: Device Under Test
SUT: System Under Test
AC: Alternating Current
IGBT: Insulated Gate Bipolar Transistor
ADC: Analog-to-Digital Converter
PLD: Programmable Logic Device
FPGA: Field Programmable Gate Array
TX/RX: Transmit/Receive
CLK: Clock
LED: Light-Emitting Diode
BCI: Battery Cell Interface
BCF: Battery Cell Fixture
PDU: Power Distribution Unit

### Terms

The following is a glossary of terms used in the present application:

Memory Medium—Any of various types of non-transitory computer accessible memory devices or storage devices. The term “memory medium” is intended to include an installation medium, e.g., a CD-ROM, floppy disks 104, or tape device; a computer system memory or random access memory such as DRAM, DDR RAM, SRAM, EDO RAM, Rambus RAM, etc.; a non-volatile memory such as a Flash, magnetic media, e.g., a hard drive, or optical storage; registers, or other similar types of memory elements, etc. The memory medium may comprise other types of non-transitory memory as well or combinations thereof. In addition, the memory medium may be located in a first computer in which the programs are executed, or may be located in a second different computer which connects to the first computer over a network, such as the Internet. In the latter instance, the second computer may provide program instructions to the first computer for execution. The term “memory medium” may include two or more memory mediums which may reside in different locations, e.g., in different computers that are connected over a network.

Carrier Medium—a memory medium as described above, as well as a physical transmission medium, such as a bus, network, and/or other physical transmission medium that conveys signals such as electrical, electromagnetic, or digital signals.

Programmable Hardware Element—includes various hardware devices comprising multiple programmable function blocks connected via a programmable interconnect. Examples include FPGAs (Field Programmable Gate Arrays), PLDs (Programmable Logic Devices), FPGAs (Field Programmable Object Arrays), and CPLDs (Complex PLDs). The programmable function blocks may range from fine grained (combinatorial logic or look up tables) to coarse grained (arithmetic logic units or processor cores). A programmable hardware element may also be referred to as “reconfigurable logic.”

Processing Element—refers to various elements or combinations of elements that are capable of performing a function in a device, such as a user equipment or a cellular network device. Processing elements may include, for example: processors and associated memory, portions or circuits of individual processor cores, entire processor cores, processor arrays, circuits such as an ASIC (Application Specific Integrated Circuit), programmable hardware elements such as a field programmable gate array (FPGA), as well any of various combinations of the above.

Software Program—the term “software program” is intended to have the full breadth of its ordinary meaning, and includes any type of program instructions, code, script and/or data, or combinations thereof, that may be stored in a memory medium and executed by a processor. Exemplary software programs include programs written in text-based programming languages, such as C, C++, PASCAL, FORTRAN, COBOL, JAVA, assembly language, etc.; graphical programs (programs written in graphical programming languages); assembly language programs; programs that have been compiled to machine language; scripts; and other types of executable software. A software program may comprise two or more software programs that interoperate in some manner. Note that various embodiments described herein may be implemented by a computer or software program. A software program may be stored as program instructions on a memory medium.

Hardware Configuration Program—a program, e.g., a netlist or bit file, that can be used to program or configure a programmable hardware element.

Program—the term “program” is intended to have the full breadth of its ordinary meaning. The term “program” includes 1) a software program which may be stored in a memory and is executable by a processor or 2) a hardware configuration program useable for configuring a programmable hardware element.

Computer System—any of various types of computing or processing systems, including a personal computer system (PC), mainframe computer system, workstation, network appliance, Internet appliance, personal digital assistant (PDA), television system, grid computing system, or other device or combinations of devices. In general, the term “computer system” can be broadly defined to encompass any device (or combination of devices) having at least one processor that executes instructions from a memory medium.

Measurement Device—includes instruments, data acquisition devices, smart sensors, and any of various types of devices that are configured to acquire and/or store data. A measurement device may also optionally be further configured to analyze or process the acquired or stored data. A measurement device may also optionally be further configured as a signal generator to generate signals for provision to a device-under-test. Examples of a measurement device include an instrument, such as a traditional stand-alone “box” instrument, a computer-based instrument (instrument on a card) or external instrument, a data acquisition card, a device external to a computer that operates similarly to a data acquisition card, a smart sensor, one or more DAQ or measurement cards or modules in a chassis, an image acquisition device, such as an image acquisition (or machine vision) card (also called a video capture board) or smart camera, a motion control device, a robot having machine vision, a signal generator, and other similar types of devices. Exemplary “stand-alone” instruments include oscilloscopes, multimeters, signal analyzers, arbitrary waveform generators, spectroscopes, and similar measurement, test, or automation instruments.

A measurement device may be further configured to perform control functions, e.g., in response to analysis of the acquired or stored data. For example, the measurement device may send a control signal to an external system, such as a motion control system or to a sensor, in response to particular data. A measurement device may also be configured to perform automation functions, i.e., may receive and analyze data, and issue automation control signals in response.

Functional Unit (or Processing Element)—refers to various elements or combinations of elements. Processing elements include, for example, circuits such as an ASIC (Application Specific Integrated Circuit), portions or circuits of individual processor cores, entire processor cores, individual processors, programmable hardware devices such as a field programmable gate array (FPGA), and/or larger portions of systems that include multiple processors, as well as any combinations thereof.

Wireless—refers to a communications, monitoring, or control system in which electromagnetic or acoustic waves carry a signal through space rather than along a wire.

Approximately—refers to a value being within some specified tolerance or acceptable margin of error or uncertainty of a target value, where the specific tolerance or margin is generally dependent on the application. Thus, for example, in various applications or embodiments, the term approximately may mean: within 0.1% of the target value, within 0.2% of the target value, within 0.5% of the target value, within 1%, 2%, 5%, or 10% of the target value, and so forth, as required by the particular application of the present techniques.

SUT Interface—one or more antenna probes and potentially supporting parts modifying the collective properties the antenna probes and parts are presenting to the electromagnetic radiation associated with wireless signals and giving structural integrity to their assembly, and which may be used to measure the wireless signals generated by the SUT.

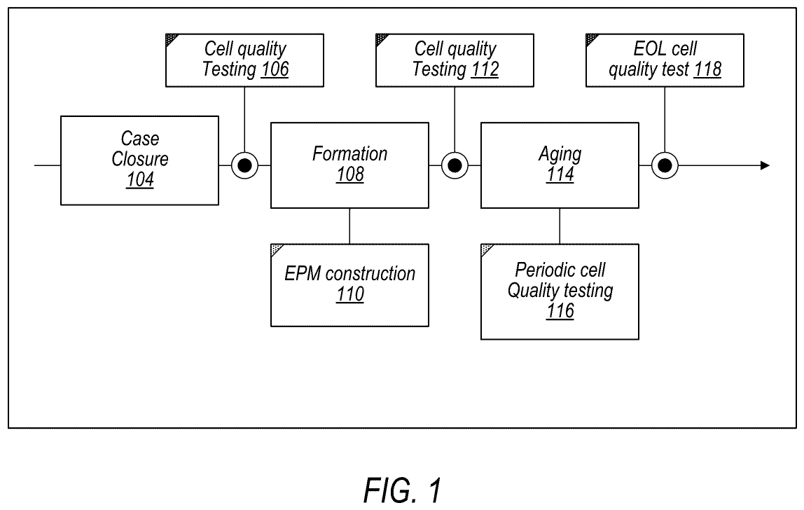

### FIG. 1—Battery Cell Manufacturing Workflow

FIG. 1 is a workflow diagram illustrating a method for manufacturing battery cells, according to some embodiments. At 104, after physically constructing the components of a battery cell, the case closure is performed to contain the battery components. At 106, the quality of the cell is tested prior to the formation process. At 108, a cell formation process is performed where the cell is repeatedly charged and discharged to establish a stable voltage difference across the anode and cathode. Embodiments herein construct an electrochemical process manifold (EPM) 110 for the cell during charging and/or discharging to assist in cell diagnostics and to improve the cell formation process.

After an electrochemical cell is assembled, its chemical structure is changed in order to become ready to use as an energy storage element. This may be done by forcing an electric current from one of the electrodes to the other, whereby an electric potential is developed across the electrodes. Whereas this process generally involves a positive net supply of energy to the cell (‘charging’), the process generally also includes periods of time where the net supply of energy is negative (‘discharging’). After a programmed sequence of current, which generally depends on the cell voltage, temperature, stored or dissipated energy, and/or time, has been applied to the cell, its production is considered complete. The production of each cell typically takes a different amount of time, mainly due to production process variations of the cell's components.

The quality of the cell may be determined through testing after completion of the formation process at step 112. The rejection rate after completing cell formation may be as high as 20%, where only 80% of the formed cells are of sufficiently high quality to proceed to aging and deployment. This may be because, during production, a considerable number of cells exhibit deviations on e.g., their temperature, terminal voltage, or another physical property. If the deviation exceeds a specified quality threshold, the production is said to have failed. Failed cells preferably are removed as early as possible from the production process, to be replaced by another cell to initiate production. Embodiments herein utilize the EPM to implement dynamic monitoring and controlling during the cell formation process to improve battery yields.

At 114, the cells that have completed the formation process and satisfied cell quality testing are moved to an aging tower to stabilize the chemical composition of the cells. The same measurement and control circuitry used in the formation process may be repurposed to periodically test cell quality during the aging process at step 116, whereby defective cells may be identified and addressed, and the cell fixture may be repurposed for a new cell. Finally, at 118 an end of line (EOL) cell quality test is performed on the aged cells prior to deploying them to market.

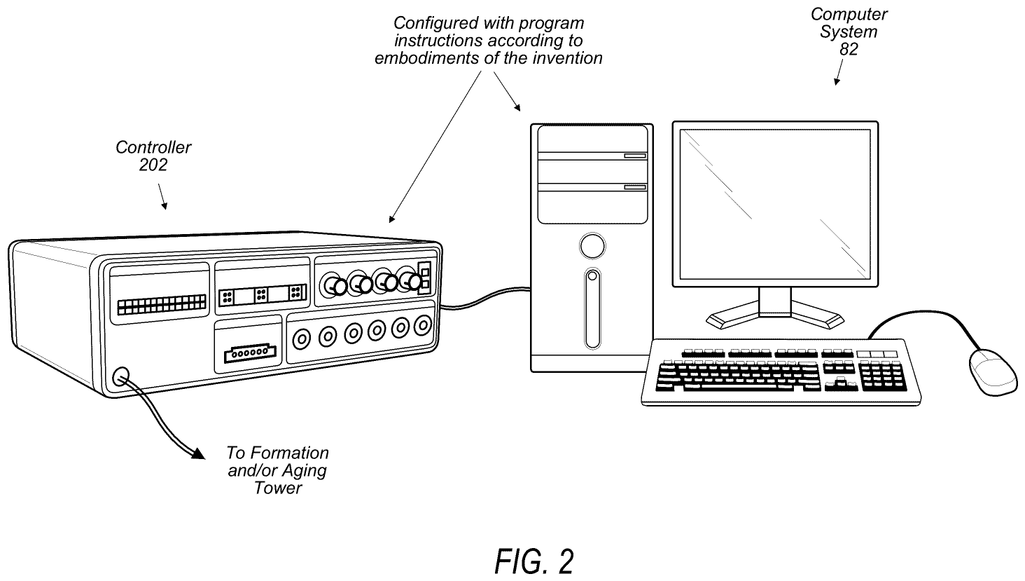

### FIG. 2—Computer System and Controller

FIG. 2 is a system diagram illustrating a computer system 82 coupled to a controller 202, according to some embodiments. The controller may be coupled via a wired or wireless connection to a formation tower and/or an aging tower, and may be configured to receive information from the formation and/or aging towers during a cell manufacturing process and provide instructions to modify parameters of the manufacturing process. For example, the controller may receive information from measurement and control circuitry that is monitoring a particular battery cell within a battery cell fixture during cell formation, and in response to this information the controller may construct the EPM, display the EPM on a display, and/or provide instructions to modify the formation process on the particular battery cell or another battery cell. Additionally or alternatively, the controller may perform analytics on the EPM, and display the analytics along with the EPM on a display device, whereby a user may determine whether to modify the manufacturing process based on the displayed information. In some embodiments, the controller may be executed from the computer system 82 (i.e., the controller may be part of the computer system rather than a separate device).

Advantageously, information provided by the EPM during the manufacturing process may enable a user to dynamically intervene in the manufacturing to improve overall yield and efficiency. For example, defective cells may be identified earlier in the manufacturing process (e.g., during the formation process or during the aging process), the defective cells may be removed from the manufacturing process for repair or disposal, and the battery cell fixtures housing the defective cells may be repurposed for the manufacture of new battery cells.

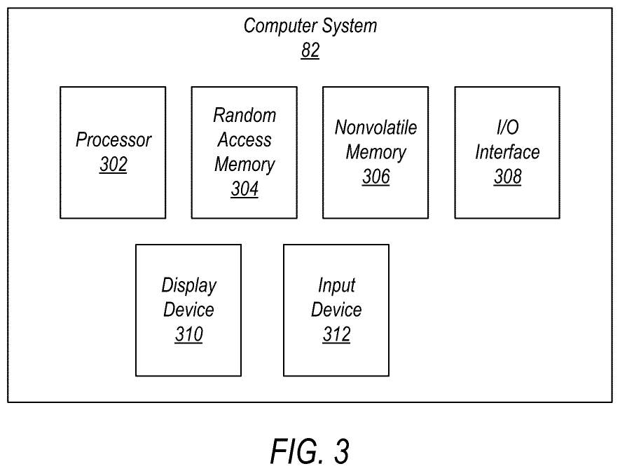

### FIG. 3—Computer System Block Diagram

FIG. 3 illustrates a simplified block diagram of the computer system 82. As shown, the computer system 82 may comprise a processor 302 that is coupled to a random access memory (RAM) 304 and a nonvolatile memory 306 to implement embodiments described herein. For example, the processor may execute program instructions stored on the nonvolatile memory to control and/or receive information from a cell formation and/or aging tower. The computer system 82 may also comprise an input device 312 for receiving user input (e.g., a keyboard, mouse, touchpad, etc.) and a display device 310 for presenting output on a display. The computer 82 may also comprise an Input/Output (I/O) interface 308 that is coupled to the controller 202 or directly to a cell tower to provide output/instructions to control cell formation and receive input and/or information related to individual cells.

### Electrochemical Process Manifold for Battery Cell Formation

Embodiments herein construct an electrochemical process manifold (EPM) for an electrochemical process and system (such as a battery cell) during the cell formation process. The EPM is a detailed construct that contains state-space mapping for a plurality of variables associated with the cell such as current, voltage, temperature, and/or pressure.

As used herein, “manifold” refers to the mathematical construct of an n-dimensional topological space, where each of the n dimensions corresponds to a state variable of the cell (e.g., current, voltage temperature, etc.). An EPM then encodes relational information of the state-history of a cell as regards the relevant variables. For example, the EPM describes a topological space whose points describe the state history of the recorded variables of the cell. Advantageously, the mathematical properties of manifolds may be leveraged to facilitate analysis of the EPM to diagnose the health of a cell. For example, the EPM may be used diagnostically to identify faulty cells earlier in the formation process, and may also be used to dynamically modify cell formation to improve yields. Various properties of the EPM (e.g., curvature, area, metric quantities, etc.) may be quantified to diagnose aspects of the cell. For example, deviation a one or more properties from those of an EPM of a reference healthy cell may be measured and quantified to diagnose the health of a cell.

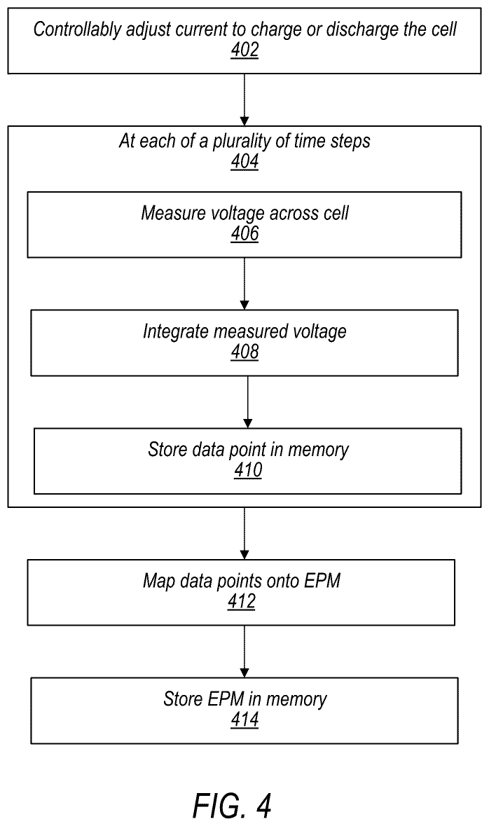

FIG. 4—Flowchart for Constructing an Electrochemical Process Manifold with Controlled Current

FIG. 4 is a flowchart diagram illustrating a method for constructing an electrochemical process manifold (EPM) while controllably adjusting current through a battery cell during a cell formation process, according to some embodiments. The method shown in FIG. 4 may be used in conjunction with any of the computer systems, battery cells, memory media or devices shown in the above Figures, among other devices.

In some embodiments, the described method may be performed during a cell formation process of a battery cell. The cell may be of any of a variety of types of battery cells, and may be composed of materials including but not limited to lithium, sodium-ions, lithium-sulfur, lithium-air, lithium-oxygen, lithium-metal, metal-flouride, carbon nanotubes, carbon nanowires, nickel cadmium (NiCd), nickel metal hydride (NiMH), lead acid, lithium cobalt oxide (LiCoO2), lithium iron phosphate (LiFePO4), lithium nickel manganese cobalt oxide (LiNiMnCoO2), lithium manganese oxide (LiMn2O4), lithium titanate (Li2TiO3), or an organic compound.

In some embodiments, a computer system may include a processor and memory, and the memory may store program instructions executable by the processor to perform the method elements described in reference to FIG. 4. In various embodiments, the processor may be a parallel multi-processor system, a field programmable gate array (FPGA), or an application specific integrated circuit (ASIC). In various embodiments, the described method steps may be directed by a combination of the controller processor (e.g., such as controller 202 in FIG. 2), and one or more processors of the computer system 82 (e.g., the processor 302. In various embodiments, some of the method elements shown may be performed concurrently, in a different order than shown, or may be omitted. Additional method elements may also be performed as desired. As shown, this method may operate as follows.

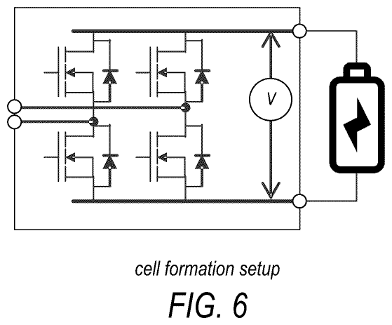

At 402, the current through the cell is controllably adjusted to charge or discharge the cell. The cell may be charged or discharged as part of a cell formation process. The current may sweep from a minimum current value to a maximum current value for the cell at each state of charge, while taking the cell from a fully discharged state to a fully charged state, or vice versa. The cell may be charged and discharged using a cell formation setup including switching circuitry to adjust the current through the cell, such as that illustrated in FIG. 6, in some embodiments.

In some embodiments, the temperature of the cell and/or a pressure applied to the cell are controllably adjusted concurrently with the controllable adjustment of the current through the cell. In some embodiments, controllably adjusting the current, temperature and pressure is performed in an oscillatory manner with a single common frequency. As used herein, the set of variables that are controllably adjusted (which may include one or more of current, voltage, temperature and pressure) are referred top as “EPM Stimulus Variables”.

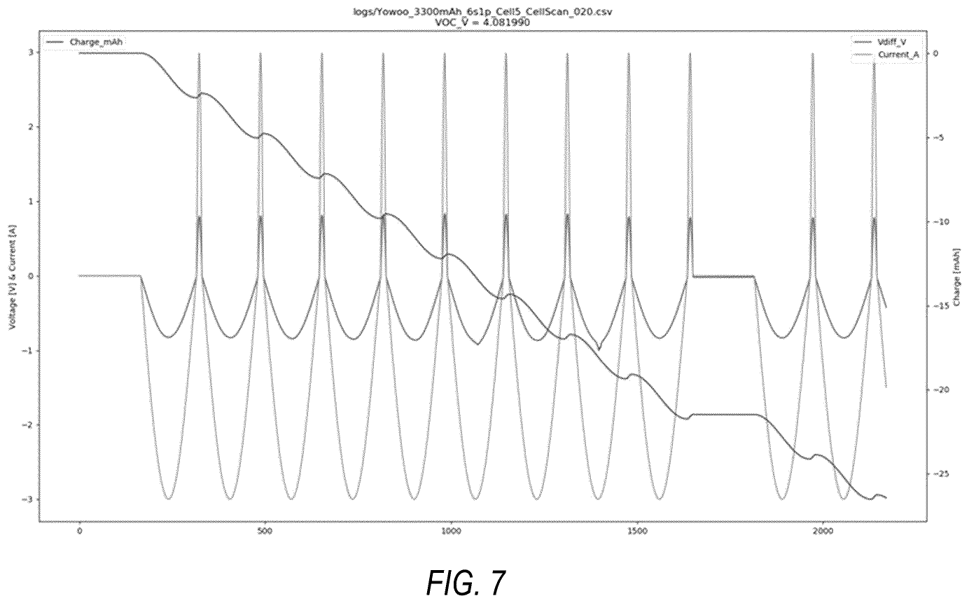

In some embodiments, the current through the cell is controllably adjusted as an oscillatory function (e.g., a sinusoidal function). Adjusting the current as an oscillatory function may enable tracking the phase angle of the current, which may be stored in the data points along with measurement data. In these embodiments, the oscillatory function may have a bias toward charging or discharging the cell, leading to a cycle of alternating charging and discharging phases with an overall bias toward charge or discharge. In some embodiments, the frequency of the oscillatory function may be adjusted every half-cycle, to create the bias toward charging or discharging. For example, for discharging, the frequency of the current waveform may be lower when the current is negative and higher when the current is positive to create a bias towards discharging. An example waveform for controllably adjusting the current is illustrated in FIG. 7. In FIG. 7, the cell is being discharged, so the half-sines when the current is negative have a lower frequency than the half-sines where the current is positive. In the illustrated example, the discharge frequency is 0.1 Hz and the charge frequency is 1.0 Hz. Note that on the 10th cycle, the current is set to zero for a cycle.

The frequency of the oscillatory function may be selected based on the interval between subsequent time steps used for constructing the EPM to measure distinct currents at the time steps during subsequent periods of oscillation of the oscillatory function. Said another way, the frequency of current oscillation may be selected such that, on subsequent periods of oscillation, the time steps occur at distinct points along the oscillatory current (such that distinct currents are measured during each subsequent period). In some embodiments, this may be accomplished by selecting the period of current oscillation to be incommensurate with the period between subsequent time steps.

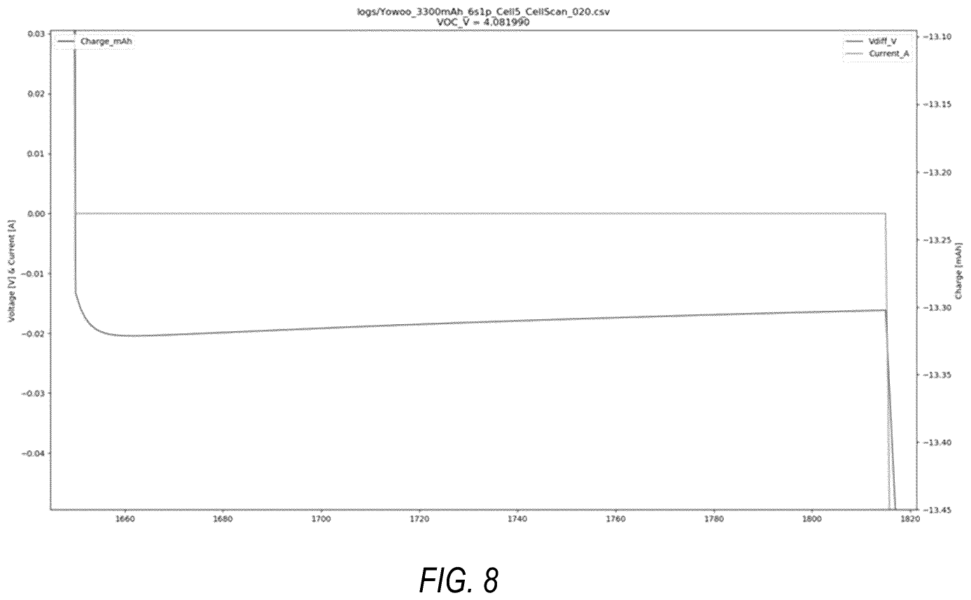

In some embodiments, the oscillatory function is modified to obtain a constant current through the cell for at least one period of the oscillatory function to determine a battery equivalent circuit model of the cell. For example, measuring the battery initial transition towards open circuit voltage at a range of states of charge may be used to predict the open circuit voltage. This may be used for the identification of battery equivalent circuit models at each state of charge. For this purpose, a counter may keep track of the number of full sinewave cycles, sineCycle. Every N cycles, the current may be set equal to 0 for a cycle, and the cell voltage response recorded. FIG. 8 illustrates the current waveform shown in FIG. 7, zoomed into the response during the zero current time at the 10^{th} cycle. Note the fast exponential curve as the voltage decreases, followed by a slow fairly linear increase. This waveform may be used to identify a battery equivalent circuit model at each state of charge where the information is collected.

At 404, various measurements and calculations are performed at each of a plurality of time steps as the current is controllably adjusted, as described in greater detail below. The set of variables that are periodically measured at each of the time steps (which may include one or more of current, voltage, temperature, and/or pressure) are referred to herein as “EPM Response Variables”.

The time steps may be separated by a constant interval, or the interval between subsequent time steps may be random or pseudorandom according to a predetermined probability distribution. In some embodiments, the distance between subsequent time steps and a pattern for adjusting the current through the cell is selected to obtain a predetermined average distance in each of current, voltage and voltage-hours between adjacent data points in the EPM.

At 406, the voltage across the cell is measured at the particular time step.

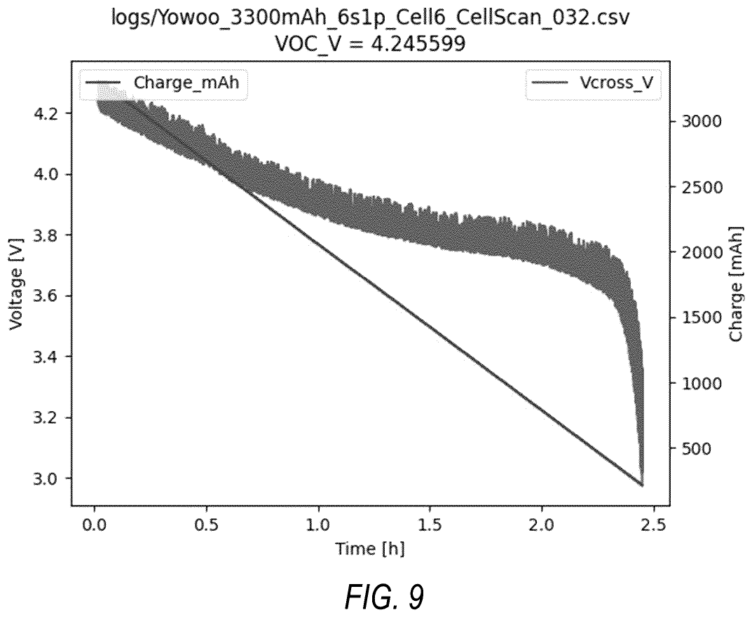

In some embodiments, the voltage may be measured at the instant that the current crosses zero, referred to as Vcross. Vcross may be used to determine when the maximum or minimum state of charge has been reached. FIG. 9 illustrates measured values of Vcross for various states of charge. Note that after the discharge cycle, Vcross is slightly lower. After the charge cycle, Vcross is slightly higher.

At 408, the measured voltage may be integrated over time to obtain a voltage-hours value for the particular time step. The voltage-hours may represent the integrated measured voltage from the start of the formation process up until the particular time step.

In some embodiments, for each time step, a derivative is taken of the current with respect to time to obtain a current rate-of-change value, and/or a derivative of the voltage is taken with respect to time to obtain a voltage rate-of-change value, for the particular time step.

At 410, a data point is stored in memory that includes the voltage-hours value, the measured voltage, and the current through the cell at the respective time step. In some embodiments, the current over time is also integrated over time to obtain a current-hours value for each time step, and the data point for each time step may further include the current-hours value. In some embodiments, the current rate-of-change values and voltage rate-of-change values may also be stored in the data point for each time step. In general, the stored data points include the EPM Stimulus Variables and the EPM Response Variables for each time step.

In some embodiments, for each time step, the temperature of the cell is measured, and the temperature is integrated over time to obtain a temperature-hours value. In these embodiments, the temperature and temperature-hours values may also be stored in the data point for each time step.

In some embodiments, for each time step, the pressure applied to the cell is measured, and this pressure is further integrated over time to obtain a pressure-hours value. In these embodiments, the pressure and pressure-hours may also be stored in the data point for each time step.

In some embodiments, the measured voltage and the current through the cell (as well as other quantities such as temperature and pressure, in at least some embodiments) are each stored in the data points as respective complex values that contain respective amplitude and phase information related to the voltage and current.

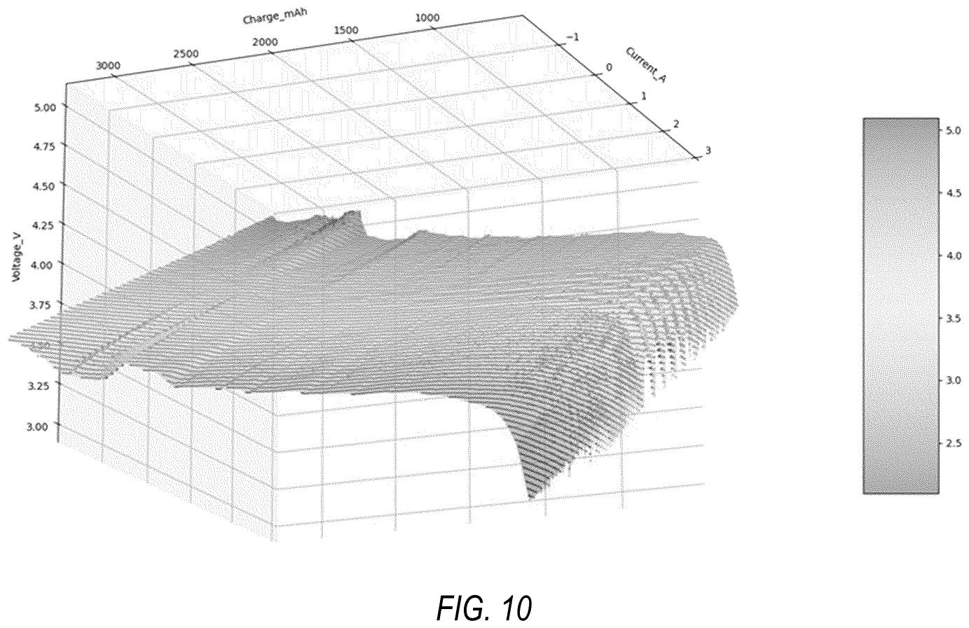

At 412, the plurality of data points is mapped onto an electrochemical process manifold (EPM). An example of an EPM is shown in FIG. 10. The EPM may be a tensor quantity that contains, for each time step, a plurality of variables at that time step including one or more of the current through the cell, the voltage across the cell, the integrated current-hours and/or voltage-hours, the rate of change of the current and/or voltage, temperature, pressure, temperature-hours, and/or pressure-hours, among other possibilities. The EPM may map the data points to a common state-space matrix in which each address represents the same state location (i.e. Current=1 A+/−0.01 A, Charge=1000 mAh+/−10 mAh). Advantageously, because the EPM is constructed as a mathematical manifold, analytics may be performed on the EPM to characterize features of the EPM. For example, properties of the EPM may be quantitatively analyzed to characterize and/or classify aspects of the cell from which the EPM was constructed.

In some embodiments, a 3-dimensional plot of the EPM is displayed on a display. Advantageously, a visual inspection of the EPM may enable a trained technician to effectively diagnose issues that may be occurring during the charge or discharge cycle.

In some embodiments, an EPM produced from preliminary cell formation data may be utilized to identify failure modes for the cell. The EPM may enable identification of good and bad cells early during the formation process. Diagnostic and/or correction instructions may be provided based on the EPM to mitigate or remove failure modes. In some embodiments, an EPM may be separately determined for each of two bad/defective cells, and they may be compared to determine whether they have the same state-space dynamics, and hence, whether they have a single or multiple different failure modes. For example, the variables described in the EPM are mapped in the quantifiable structure of the manifold, such that relationships and dynamics between the variables may be quantified and compared between EPMs of different cells. As one example, it may be quantified how current varies as a joint function of voltage and temperature, and certain characteristic dependencies may be identified with potential failure modes of the cell, or they may be identified as a healthy cell.

In some embodiments, patterns may be identified in the EPM to correspond to particular failure modes for the formation process. In some embodiments, the cell formation processes may be dynamically modified based on the EPM to improve formation performance. Dynamic feedback may be implemented between developing an EPM for a cell during formation and providing feedback to modify the formation process to improve formation.

In some embodiments, the EPM is provided to a processor (or set of processors) executing a machine-learning algorithm. The machine-learning algorithm may have been previously trained to analyze the EPM to provide a variety of types of predictive, diagnostic, or other information related to the cell formation process. For example, based at least in part on the EPM, the machine-learning algorithm may determine a quality assessment of the cell, a prediction of a Coulomb efficiency of the cell, and/or information predicting one or more quality metrics of the cell after completion of the formation process on the cell, among other possibilities.

In these embodiments, the machine-learning algorithm may produce, based on the EPM, instructions to modify the formation process of the cell to improve a quality metric of the cell when the formation process is complete.

In some embodiments, the EPM may be provided to the machine-learning algorithm along with partial formation data for a second cell. In these embodiments, the machine-learning algorithm may determine a quality metric for the second cell using the EPM and the partial formation data for the second cell.

At 414, the EPM is stored in a non-transitory computer-readable memory medium.

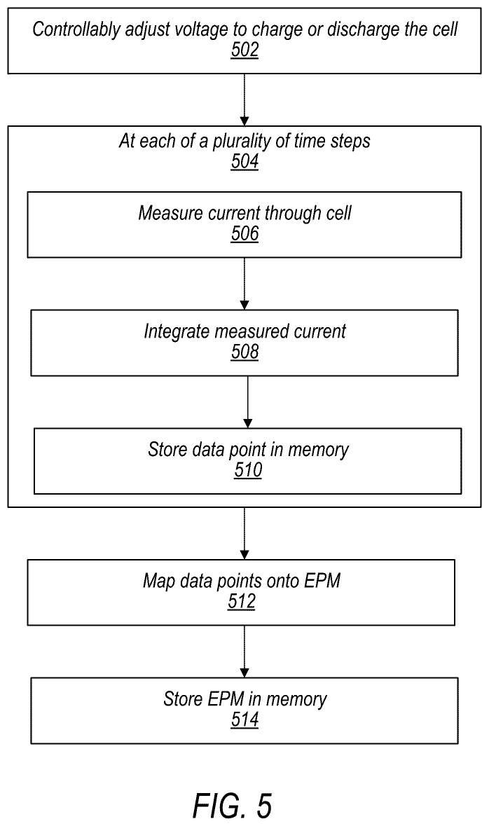

FIG. 5—Flowchart for Constructing an Electrochemical Process Manifold with Controlled Voltage

FIG. 5 is a flowchart diagram illustrating a method for constructing an electrochemical process manifold (EPM) while controllably adjusting voltage across a battery cell during a cell formation process, according to some embodiments. The method shown in FIG. 5 may be used in conjunction with any of the computer systems, battery cells, memory media or devices shown in the above Figures, among other devices. The method shown in FIG. 5 is similar in some respects to the method shown in FIG. 4, with the exception that in FIG. 5 the voltage is controllably adjusted and the current is periodically measured, whereas in FIG. 4 the current is controllably adjusted and the voltage is periodically measured. Note that various aspects of the description of FIG. 4 may apply equally to the method described in FIG. 5, as appropriate.

### Additional Technical Description

The following numbered paragraphs described additional aspects of the described embodiments.

While embodiments herein are described in the context of charging and discharging a battery cell to produce an electrochemical process manifold (EPM), it is within the scope of the present disclosure to produce an EPM for any of a variety of broader types of electrochemical processes, and the described embodiments are not limited to battery cells. For example, any material or device that undergoes an electrochemical process may be controllably exposed to one or more of current, voltage, temperature or pressure variations, measured for one or more of these variables during said exposure, and these data points may be mapped onto an EPM.

In various embodiments, either the current may be directly controlled (and voltage is periodically measured), or the voltage may be directly controlled (and current is periodically measured). In some embodiments, for ‘current control mode’ temperature and pressure may be controlled in addition to controlling current, so voltage is the dependent variable. Similarly, in some embodiments, for ‘voltage control mode’ temperature and pressure may be controlled in addition to voltage and current is the dependent variable. However, in some embodiments satisfactory but less information-rich EPMs may be obtained with less effort if temperature and pressure are uncontrolled and/or unmeasured. In some embodiments, temperature and pressure are controlled such that they oscillate at the same frequency as the current for current control mode, or the same frequency as voltage for voltage control mode. Advantageously, this may enable an easier calculation of the phase relationship between the variables which yields more information about the electrochemical processes.

In some embodiments, the phase angle of the voltage is computed relative to the phase angle of the controlled current and other variables. This is a coordinate transformation from the time domain to a rotating reference frame aligned with the other signal (for example, the current phasor.) Each value (i.e., voltage, temperature, pressure) sampled in the time domain may be described in terms of its amplitude and also its phase angle relative to the other variables, and this phase angle relationship yields valuable information about the electrochemical process and therefore helps in constructing a more information-rich EPM. As an example, an oscillatory variation in temperature produces an oscillatory voltage response and the nature of the voltage response contains information about the electrochemical processes that are currently underway. To keep the phase angle calculations simpler, the cell temperature may be varied at the same frequency as the electrical control variable (current in the case of current control or voltage in the case of voltage control). Various methods may be used to compute the relative phase angles and to control the temperature phase angle. To include phase information in a compact numerical form, each transformed variable can be expressed as a vector, such as a complex number or a higher dimensional vector in the EPM subspace (i.e., for each location on the EPM mesh-grid, compute each of: the component of voltage that is parallel to temperature, the component of voltage that is orthogonal to temperature, the component of voltage that is parallel to current, the component of voltage that is orthogonal to current, etc.). Mathematically, the time domain data is mapped onto the electrochemical process manifold, because manifolds have well defined mathematical properties that facilitate interpretation and analysis.

In various embodiments, different processes are implemented to map the time-series data points (i.e., the sequence of data points that each include a time stamp, current value, voltage value, current-hours value, voltage-hours value, etc.) onto the EPM. For example, in some embodiments a conventional method is utilized where, for each set of data sampled in the time domain (“set” here refers to simultaneously sampled voltage, voltage_hours, current, current_hours, etc.), identify the nearest grid point on the N-dimensional EPM mesh-grid and perform data aggregation to update the mesh-grid value at that location with the mean value of all samples that are closest to the mesh-grid location in N-dimensional space. This is a coordinate transformation to a discrete manifold with averaging of the time domain data. Doing this is a form of data compression, since the values for each location in the discrete manifold are the average of all time domain samples within range. Thus, we have the option to discard the time-series data and only store the dense manifold values. An ideal EPM Scanner algorithm ensures we collect at least S samples for each location in the EPM mesh-grid, where S≥1.

In other embodiments, a machine learning method may be used to map the time-series data points to the EPM. Based on prior knowledge of many EPM mesh-grids for complete electrochemical processes, the most likely mesh-grid may be identified that explains one or more sets of data sampled in the time domain, optionally given incomplete time series data. This has the desirable properties of the conventional method such as coordinate transformation and data compression, but adds important additional benefits such as 1) the ability to perform intelligent non-linear interpolation between unsampled data points in the EPM mesh-grid given a priori knowledge of many EPMs, and 2) the ability to predict the EPM for an entire electrochemical process before that process has been completed. In this case, the confidence level in the EPM prediction increases with time and reaches 100 percent at the completion of the electrochemical process.

### Additional Embodiments

The following paragraphs describe additional embodiments.

In some embodiments, a method is described for performing a monitored charge or discharge of a cell. The method may include controllably adjusting a voltage across the cell to charge or discharge the cell. At each respective time step of a plurality of time steps as the voltage is controllably adjusted, a respective current through the cell may be measured and the measured current may be integrated over time to obtain a respective current-hours value for the respective time step. A respective data point may be stored including the respective current-hours value, the respective measured current, and the voltage across the cell at the respective time step. The plurality of data points may be mapped onto an electrochemical process manifold (EPM). The EPM may be stored in a non-transitory computer-readable memory medium.

In some embodiments, the method further comprises, at each respective time step of the plurality of time steps, integrating the voltage over time to obtain a respective voltage-hours value, wherein the respective data points further comprise the respective voltage-hours values.

In some embodiments, the method further comprises, at each respective time step of the plurality of time steps, measuring a respective temperature of the cell, and integrating the temperature over time to obtain a respective temperature-hours value. In these embodiments, the respective data points may further include the respective temperatures and the respective temperature-hours values.

In some embodiments, the method further comprises, at each respective time step of the plurality of time steps, measuring a respective pressure applied to the cell, and integrating the pressure over time to obtain a respective pressure-hours value. In these embodiments, the respective data points may further include the respective pressures and the respective pressure-hours values.

In some embodiments, the method further comprises displaying a 3-dimensional plot of the EPM on a display.

In some embodiments, the method further comprises providing the EPM to at least one processor executing a machine-learning algorithm; and receiving, from the at least one processor, a quality assessment of the cell that is determined based at least in part on the EPM.

In some embodiments, the method further comprises providing the EPM to at least one processor executing a machine-learning algorithm; and receiving, from the processor a prediction of a Coulomb efficiency of the cell determined based at least in part on the EPM.

In some embodiments, the voltage across the cell is controllably adjusted as an oscillatory function, and a frequency of the sinusoidal oscillatory function is selected based at least in part on an interval between the plurality of time steps to measure distinct voltages at the time steps during subsequent periods of oscillation of the oscillatory function.

In some embodiments, the oscillatory function has a bias toward charging or discharging the cell.

In some embodiments, the method further comprises modifying the oscillatory function to obtain a constant voltage across the cell for at least one period of the oscillatory function to determine a battery equivalent circuit model of the cell.

In some embodiments, the method further comprises providing the EPM to at least one processor executing a machine-learning algorithm; and receiving, from the at least one processor, instructions to modify a formation process to improve a quality metric of the cell when the formation process is complete, wherein the instructions are determined by the machine learning algorithm based at least in part on the EPM.

In some embodiments, the method further comprises providing the EPM to at least one processor executing a machine-learning algorithm; and receiving, from the at least one processor, information predicting one or more quality metrics of the cell after performing a formation process on the cell.

In some embodiments, the method further comprises providing the EPM to at least one processor executing a machine-learning algorithm; providing, to the at least one processor, partial formation data for a second cell; and determining, by the at least one processor, a quality metric for the second cell based at least in part on the EPM and the partial formation data for the second cell.

In some embodiments, the method further comprises selecting a distance between subsequent time steps of the plurality of time steps and a pattern for adjusting the voltage across the cell to obtain a respective predetermined average distance in each of current, voltage and voltage-hours between adjacent data points in the EPM.

In some embodiments the cell is a battery cell composed of one of lithium, sodium-ions, lithium-sulfur, lithium-air, lithium-oxygen, lithium-metal, metal-fluoride, carbon nanotubes, carbon nanowires, nickel cadmium (NiCd), nickel metal hydride (NiMH), lead acid, lithium cobalt oxide (LiCoO2), lithium iron phosphate (LiFePO4), lithium nickel manganese cobalt oxide (LiNiMnCoO2), lithium manganese oxide (LiMn2O4), lithium titanate (Li2TiO3), or an organic compound.

In some embodiments, the voltage and current are each stored in the data points as respective complex values that contain respective amplitude and phase information related to the voltage and current.

In some embodiments, the method further comprises, at each respective time step of the plurality of time steps, taking a derivative of the current over time to obtain a respective current rate-of-change value, and taking a derivative of the voltage over time to obtain a respective voltage rate-of-change value. In these embodiments, the respective data points further include the respective current rate-of-change values and voltage rate-of-change values.

In some embodiments, the method further comprises controllably adjusting a temperature of the cell and a pressure applied to the cell concurrently with said controllably adjusting the voltage across the cell.

In some embodiments, controllably adjusting the voltage, temperature and pressure is performed in an oscillatory manner with a single common frequency.

In some embodiments, the described methods may be performed by a standard computer processor coupled to memory. Alternatively, in some embodiments a programmable hardware element may be utilized to perform the described methods. A programmable hardware element may include various hardware devices comprising multiple programmable function blocks connected via a programmable interconnect. Examples include FPGAs (Field Programmable Gate Arrays), PLDs (Programmable Logic Devices), FPGAs (Field Programmable Object Arrays) and CPLDs (Complex PLDs). The programmable function blocks may range from fine grained (combinatorial logic or look up tables) to coarse grained (arithmetic logic units, graphics processing units (GPUs), or processor cores). A programmable hardware element may also be referred to as “reconfigurable logic.” As another option, an integrated circuit with dedicated hardware components such as an Application Specific Integrated Circuit (ASIC) may be used to perform the described method steps.

Although the embodiments above have been described in considerable detail, numerous variations and modifications will become apparent to those skilled in the art once the above disclosure is fully appreciated. It is intended that the following claims be interpreted to embrace all such variations and modifications.

What is claimed is:

1. A method, for performing a monitored charge or discharge of a cell, the method comprising:
controllably adjusting a current through the cell to charge or discharge the cell;
at each respective time step of a plurality of time steps as the current is controllably adjusted:
measuring a respective voltage across the cell;
integrating the measured voltage over time to obtain a respective voltage-hours value for the respective time step; and
storing a respective data point comprising the respective voltage-hours value, the respective measured voltage, and the current through the cell at the respective time step; and
mapping the plurality of data points onto an electrochemical process manifold (EPM); and
storing the EPM in a non-transitory computer-readable memory medium.

2. The method of claim 1, further comprising:
at each respective time step of the plurality of time steps:
integrating the current over time to obtain a respective current-hours value, wherein the respective data points further comprise the respective current-hours values.

3. The method of claim 1, the method further comprising;
at each respective time step of the plurality of time steps:
measuring a respective temperature of the cell;
integrating the temperature over time to obtain a respective temperature-hours value,
wherein the respective data points further comprise the respective temperatures and the respective temperature-hours values.

4. The method of claim 1, the method further comprising;
at each respective time step of the plurality of time steps:
measuring a respective pressure applied to the cell;
integrating the pressure over time to obtain a respective pressure-hours value,
wherein the respective data points further comprise the respective pressures and the respective pressure-hours values.

5. The method of claim 1, further comprising:
displaying a 3-dimensional plot of the EPM on a display.

6. The method of claim 1, further comprising:
providing the EPM to at least one processor executing a machine-learning algorithm; and
receiving, from the at least one processor, a quality assessment of the cell that is determined based at least in part on the EPM.

7. The method of claim 1, further comprising:
providing the EPM to at least one processor executing a machine-learning algorithm; and
receiving, from the at least one processor, a prediction of a Coulomb efficiency of the cell determined based at least in part on the EPM.

8. The method of claim 1,
wherein the current through the cell is controllably adjusted as an oscillatory function; and
wherein a frequency of the oscillatory function is selected based at least in part on an interval between the plurality of time steps to measure distinct currents at the time steps during subsequent periods of oscillation of the oscillatory function.

9. The method of claim 8,
wherein the oscillatory function comprises a bias toward charging or discharging the cell.

10. The method of claim 8, further comprising:
modifying the oscillatory function to obtain a constant current through the cell for at least one period of the oscillatory function to determine a battery equivalent circuit model of the cell.

11. The method of claim 1, further comprising:
providing the EPM to at least one processor executing a machine-learning algorithm; and
receiving, from the at least one processor, instructions to modify a formation process to improve a quality metric of the cell when the formation process is complete, wherein the instructions are determined by the machine learning algorithm based at least in part on the EPM.

12. The method of claim 1, further comprising:
providing the EPM to at least one processor executing a machine-learning algorithm; and
receiving, from the at least one processor, information predicting one or more quality metrics of the cell after performing a formation process on the cell.

13. The method of claim 1, further comprising:
providing the EPM to at least one processor executing a machine-learning algorithm;
providing, to the at least one processor, partial formation data for a second cell; and
determining, by the at least one processor, a quality metric for the second cell based at least in part on the EPM and the partial formation data for the second cell.

14. The method of claim 1, further comprising:
selecting a distance between subsequent time steps of the plurality of time steps and a pattern for adjusting the current through the cell to obtain a respective predetermined average distance in each of current, voltage and voltage-hours between adjacent data points in the EPM.

15. The method of claim 1, wherein the cell comprises a battery cell composed of one of:
lithium;
sodium-ions
lithium-sulfur;
lithium-air;
lithium-oxygen;
lithium-metal;
metal-fluoride;
carbon nanotubes;
carbon nanowires,
nickel cadmium (NiCd);
nickel metal hydride (NiMH);
lead acid;
lithium cobalt oxide (LiCoO2);
lithium iron phosphate (LiFePO4);
lithium nickel manganese cobalt oxide (LiNiMnCoO2);
lithium manganese oxide (LiMn2O4);
lithium titanate (Li2TiO3); or
an organic compound.

16. The method of claim 1,
wherein the measured voltage and current through the cell are each stored in the data points as respective complex values that contain respective amplitude and phase information related to the voltage and current.

17. The method of claim 1, further comprising:
at each respective time step of the plurality of time steps:
taking a derivative of the current over time to obtain a respective current rate-of-change value; and
taking a derivative of the voltage over time to obtain a respective voltage rate-of-change value,
wherein the respective data points further comprise the respective current rate-of-change values and voltage rate-of-change values.

18. The method of claim 1, further comprising:
controllably adjusting a temperature of the cell and a pressure applied to the cell concurrently with said controllably adjusting the current through the cell,
wherein controllably adjusting the current, temperature and pressure is performed in an oscillatory manner with a single common frequency.

19. A non-transitory computer-readable memory medium storing program instructions which, when executed by one or more processors:
cause a cell formation device to controllably adjust a current through a cell to charge or discharge the cell;
at each respective time step of a plurality of time steps as the current is controllably adjusted:
measure a respective voltage across the cell;
integrate the measured voltage over time to obtain a respective voltage-hours value for the respective time step; and
store a respective data point comprising the respective voltage-hours value, the respective measured voltage, and the current through the cell at the respective time step; and
map the plurality of data points onto an electrochemical process manifold (EPM); and
store the EPM in a non-transitory computer-readable memory medium.

20. An apparatus, comprising:
a non-transitory computer-readable memory medium;
one or more processors coupled to the memory medium; and
circuitry coupled to the one or more processors and configured to interface with a cell, wherein the apparatus is configured to:
controllably adjust a current through the cell to charge or discharge the cell;
at each respective time step of a plurality of time steps as the current is controllably adjusted:
measure a respective voltage across the cell;
integrate the measured voltage over time to obtain a respective voltage-hours value for the respective time step; and
store a respective data point comprising the respective voltage-hours value, the respective measured voltage, and the current through the cell at the respective time step; and
map the plurality of data points onto an electrochemical process manifold (EPM); and
store the EPM in a non-transitory computer-readable memory medium.
